(19) United States
(12) Patent Application Publication
(10) Pub. No.: US 2021/0329811 A1
(43) Pub. Date: Oct. 21, 2021

(54) SUB-AMBIENT COOLING SYSTEM WITH CONDENSATION CONTROL FOR USE WITH ELECTRONIC DEVICES AND RELATED METHODS

(71) Applicant: Intel Corporation, Santa Clara, CA (US)

(72) Inventors: Mark MacDonald, Beaverton, OR (US); Akhilesh Rallabandi, Chandler, AZ (US); Ellann Cohen, Hillsboro, OR (US); Michael Nakanishi, Happy Valley, OR (US); John Carver, Portland, OR (US); Arturo Navarro Alvarez, Belen (CR); Oleg Krishcko, Portland, OR (US)

(21) Appl. No.: 17/359,134

(22) Filed: Jun. 25, 2021

(51) Int. Cl. H05K 7/20

(52) U.S. Cl. CPC H05K 7/2039; H05K 7/20136; G06F 1/203; H05K 7/20336; H05K 7/20327

(57) ABSTRACT

Sub-ambient cooling systems with condensation mitigation for use with electronic devices are disclosed. An example sub-ambient cooling assembly disclosed herein includes a heat spreader to remove heat from an electronic component. A thermal electric cooler that is to remove heat from the heat spreader. A heat exchanger to remove heat from the thermal electric cooler, where the thermal electric cooler is positioned between the heat spreader and the heat exchanger. A shroud is to at least partially surround the heat spreader and the thermal electric cooler, where the heat exchanger is to transfer heat to the shroud to increase a surface temperature of the shroud.

### FIELD OF THE DISCLOSURE

This disclosure relates generally to electronic devices, and, more particularly, to sub-ambient cooling system with condensation control for use with electronic devices and related methods.

### BACKGROUND

Electronic devices utilize thermal systems to manage thermal conditions for maintaining optimal efficiency and/or performance. To manage thermal conditions, electronic devices employ thermal cooling systems that cool electronic components of the electronic devices during use.

### DESCRIPTION OF THE DRAWINGS

FIG. 1 is a front view of an example electronic device having an example thermal cooling system in accordance with teachings of this disclosure.

FIG. 2 is a trimetric view of an example sub-ambient cooler assembly of the example thermal cooling system of FIG. 1 constructed in accordance with teachings disclosed herein

FIG. 3A is a cross-sectional, trimetric view of the example sub-ambient cooler assembly of FIG. 2 taken along line 3-3 of FIG. 2.

FIG. 3B is a front, cross-sectional view of FIG. 3A.

FIG. 4 is a front, cross-sectional view similar to FIG. 3B illustrating an example schematic heat distribution profile of the example sub-ambient assembly during an example operation.

FIG. 5. is a cross-sectional view of the example sub-ambient cooler assembly of FIGS. 2, 3A and 3B implemented with an example supplemental heating system disclosed herein.

FIG. 6. is a cross-sectional view of the example sub-ambient cooler assembly of FIGS. 2, 3A and 3B implemented with another example supplemental heating system disclosed herein.

FIG. 7 is another example sub-ambient cooler assembly disclosed herein.

FIG. 8A is a side view of the example sub-ambient cooler assembly of FIG. 7 but shown without an example wicking material.

FIG. 8B is a partially assembled view of the example sub-ambient cooler assembly of FIG. 7 shown with an example shroud removed from the example sub-ambient cooler assembly.

FIG. 9 is a flowchart of an example method of manufacturing an example sub-ambient cooler assembly disclosed herein.

The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular. In general, the same reference numbers will be used throughout the drawing(s) and accompanying written description to refer to the same or like parts. As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another. As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc. are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name. As used herein, “approximately” and “about” refer to dimensions that may not be exact due to manufacturing tolerances and/or other real world imperfections.

### DETAILED DESCRIPTION

Over the past years, personal computing devices have decreased in size (e.g., employ a smaller and lighter form factor) while increasing in computing power (e.g., running more powerful processors). In these types of personal computing devices, thermal management is important to both computing performance and user experience. For example, during operation of an electronic device (e.g., a desktop computer, a server, a laptop, a tablet, a mobile device, a head set, a virtual reality headset, wearable devices, electronic glasses, etc.), hardware components, such as a processor, a graphics card, a battery and/or other electronic components disposed in a body or housing of the device generate heat. Heat generated by the hardware components of the electronic device can cause a temperature of one or more electronic components to exceed operating temperature limits of the one or more electronic components. In some instances, heat generated by the electronic device (e.g., a mobile or portable device) can cause portions of an exterior surface, or skin, of a device housing to increase and become warm or hot to a user's touch. Thus, as processor power increases and device form factor decreases, the ability to dissipate generated heat from the processor improves device performance. For example, failing to effectively reject generated heat can reduce or decrease performance of the electronic device that can be noticed by users in slower functioning computers.

To prevent overheating of the hardware components and/or damage to the device when the user touches or places one or more portions of the user's body proximate to the skin of the device and/or components of the device accessible via the exterior surface of a housing such as a tablet, electronic devices often employ a thermal management system to dissipate heat from the electronic device. Example thermal systems include active cooling systems or passive cooling systems. Active cooling systems employ forced convention methods to increase a rate of fluid flow, which increases a rate of heat removal. For example, to exhaust heat or hot air generated within the body of the electronic device and cool the electronic device, active cooling systems often employ external devices such as fans or blowers, forced liquid, thermoelectric coolers, etc. However, ambient convective cooling systems (e.g., traditional active cooling systems that employ fans and heat sinks, etc.) cannot cool the electronic components (e.g., processors) to a temperature that is less than ambient (room) temperature.

To reduce a temperature of electronic components to temperatures that are below (e.g., less than) ambient (room) temperature, some electronic devices employ sub-ambient cooling systems. Sub-ambient cooling systems enable processor or CPU operation at frequencies that are greater than a maximum design or recommended frequency, which is commonly referred to as overclocking. For example, cooling a processor below ambient temperature enables peak processor performance beyond what can be achieved when employing traditional liquid and air cooling solutions (e.g., water blocks, water-cooled loops, fans, etc.), as those solutions are typically limited to ambient temperatures.

To reduce a temperature of an electronic device to sub-ambient temperatures, some systems employ liquid nitrogen for cooling electronic components to a temperature below ambient temperature. However, liquid nitrogen is costly and not be readily available.

Some example sub-ambient temperature cooling employ refrigeration systems to lower temperatures below ambient (room) temperatures that allow for higher frequency performance of electronic components. For example, sub-ambient cooling systems employ refrigeration systems or comparable devices between a processor and a heat sink. For instance, sub-ambient cooling systems employ thermal electric coolers (TEC) to reduce temperatures below ambient. Sub-ambient cooling systems cool electronic components to temperatures that are below ambient (room) temperature, thereby reducing surface temperatures of electronic components (e.g., processor, a silicon die) and, thereby improving performance efficiency. For example, sub-ambient cooling systems enable a processor to run at a frequency of 5.8 GHz (gigahertz) while maintaining a silicon junction temperature at approximately 30 degrees Celsius.

Although sub-ambient cooling systems improve efficiency of electronic components and/or reducing external surface temperatures of electronic devices by cooling the electronic components to temperatures that are less than ambient (room) temperatures, some known sub-ambient cooling systems are susceptible to condensation. For example, sub-ambient cooling systems can cool surface temperatures of electronic components to temperatures that are less than ambient (room) temperatures. Condensation can form on surfaces of electronic components when the surfaces are subject to temperature differentials. For example, condensation is prone to formation when warmer, moisture-laden air contacts a cooler surface. As temperature of air adjacent a surface of the electronic component reduces (e.g., cools), the cooler air can hold less moisture. In turn, condensation, or water, forms on the surface of the electronic component when the air adjacent the surface cools to a temperature (e.g., a dewpoint temperature) where the air can no longer hold as much or additional moisture, causing deposition of seater on the cool surface For example, when a temperature of the surface falls below a dewpoint temperature of air in a volume directly exposed to the surface of the electronic component, condensation can form on the surface of the electronic component. As used herein, dewpoint means a temperature at which water vapor in any static or moving air column will condense into water. In other words, the air is saturated and can no longer hold any additional moisture at this temperature. When the air temperature drops below its dew point, excess moisture will be released in the form of condensation.

Example apparatus disclosed herein prevent and/or reduce condensation (e.g., condensed water) on surfaces cooled by sub-ambient cooling systems. For example, apparatus disclosed herein prevent or reduce condensation of liquid on electronic components (e.g., critical electronic components such as, for example, processors, etc.) adjacent system on chips (SOC) when employing sub-ambient cooling systems for overclocking of unlocked processors and/or reducing external surface temperatures of the electronic devices.

To prevent or reduce condensation from forming on surfaces of electronic components when cooling the electronic components to sub-ambient temperatures, some example apparatus disclosed herein increase surface temperatures of the electronic components (adjacent the electronic components cooled to sub-ambient temperatures) to prevent air adjacent surfaces of the electric components (adjacent the electronic components cooled to sub-ambient temperatures) from cooling below a dewpoint temperature of the air. In some examples, example apparatus disclosed herein employ convection and/or conduction heating to increase surface temperatures of electronic components to prevent or reduce the surface temperatures from falling below a dewpoint temperature of air when cooling proximate or adjacent electronic components to temperatures below sub-ambient temperatures. In other words, example apparatus disclosed herein target specific surfaces of electronic components that can be susceptible to condensation when cooling other electronic components of an electronic device to temperatures below sub-ambient temperatures.

In some examples, example apparatus disclosed herein employ wicking material (e.g., a wick or wick pad) to collect condensation and distribute or channel condensation to a remote location positioned away from certain electronic components (e.g., processor(s), system on chip (SOC), circuit board, etc.). In some examples, condensed water collected by the wick or wicking material can be evaporated (e.g., via heat, fans, blowers, etc.) from the wicking material.

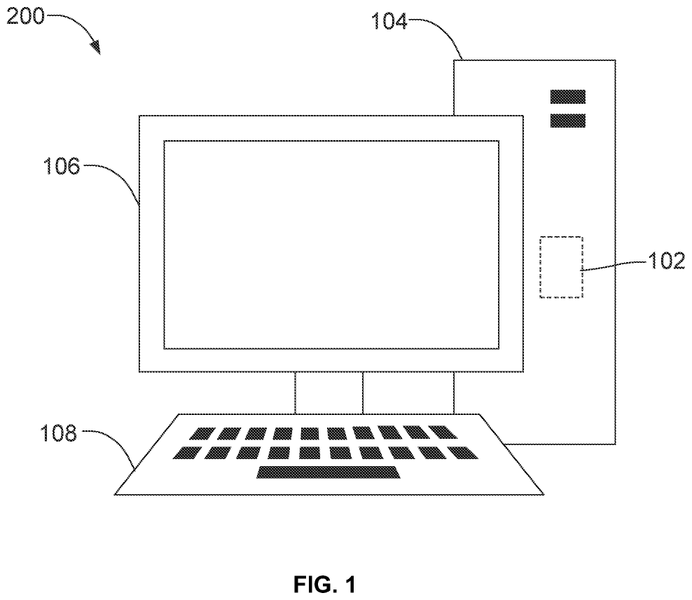

FIG. 1 is a front view of an example electronic device 100 having an example thermal cooling system 102 in accordance with teachings of this disclosure. The electronic device 100 of the illustrated example is a desktop computer 104 having a monitor 106 and a keyboard 108. The desktop computer 104 contains or houses the thermal cooling system 102 disclosed herein. However, the example thermal cooling system 102 disclosed herein is not limited to the example electronic device 100 of FIG. 1. In some examples, the example thermal cooling system 102 disclosed herein can be provided with other electronic devices including, but not limited to, a laptop computer, a tablet, a mobile device or phone, wearable glasses, augmented and/or virtual reality headgear, gaming consoles, and/or any other electric device(s) and/or wearable device(s).

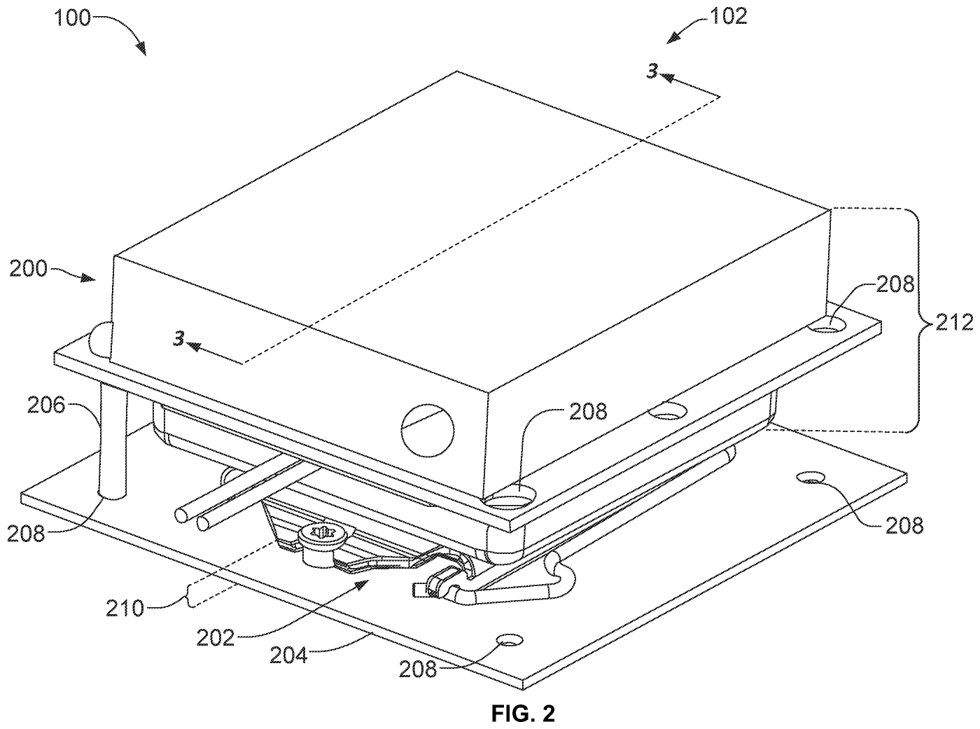

FIG. 2 is a perspective view of an example sub-ambient cooler assembly 200 of the example thermal cooling system 102 constructed in accordance with teachings disclosed herein. The sub-ambient cooler assembly 200 of the illustrated example provides sub-ambient cooling to one or more electronic components 202 of a circuit board assembly 204 of the electronic device 100. The sub-ambient cooler assembly 200 of the illustrated example removably couples to a circuit board assembly 204 of the electronic device 100. For example, the sub-ambient cooler assembly 200 of the illustrated example is removably coupled to the circuit board assembly 204 via fasteners 206 (only one shown in FIG. 2) that pass through respective openings 208 of the sub-ambient cooler assembly 200 and the circuit board assembly 204. As described in greater detail below, the sub-ambient cooler assembly 200 of the illustrated example controls and/or otherwise prevents condensation (e.g., condensed water) from forming proximate the electronic components 202 of the circuit board assembly 204 while cooling the electronic components 202 to temperatures that are below ambient.

In the illustrated example, the circuit board assembly 204 (e.g., and the electronic components 202) is a first assembly 210 and the sub-ambient cooler assembly 200 is a second assembly 212 that is separate from the first assembly 210. For example, the circuit board assembly 204 is manufactured and/or assembled separately (e.g., as a first assembly) from the sub-ambient cooler assembly 200 (e.g., a second assembly). Thus, in some examples, the sub-ambient cooler assembly 200 of the illustrated example can be assembled with the circuit board assembly 204 during manufacturing or assembly of the electronic device 100. Alternatively, in some examples, the sub-ambient cooler assembly 200 can be retrofit with existing circuit board assemblies and/or electronic devices. Thus, the sub-ambient cooler assembly 200 of the illustrated example can be an after-market product that can be installed with (e.g., coupled to) the electronic device 100 by an end user of the electronic device 100.

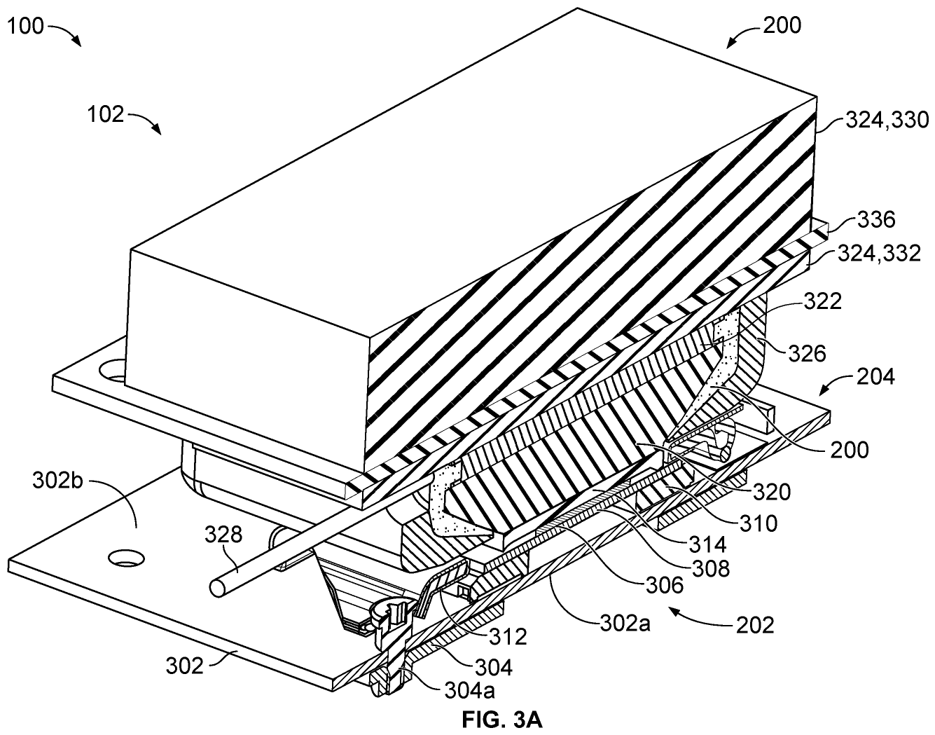

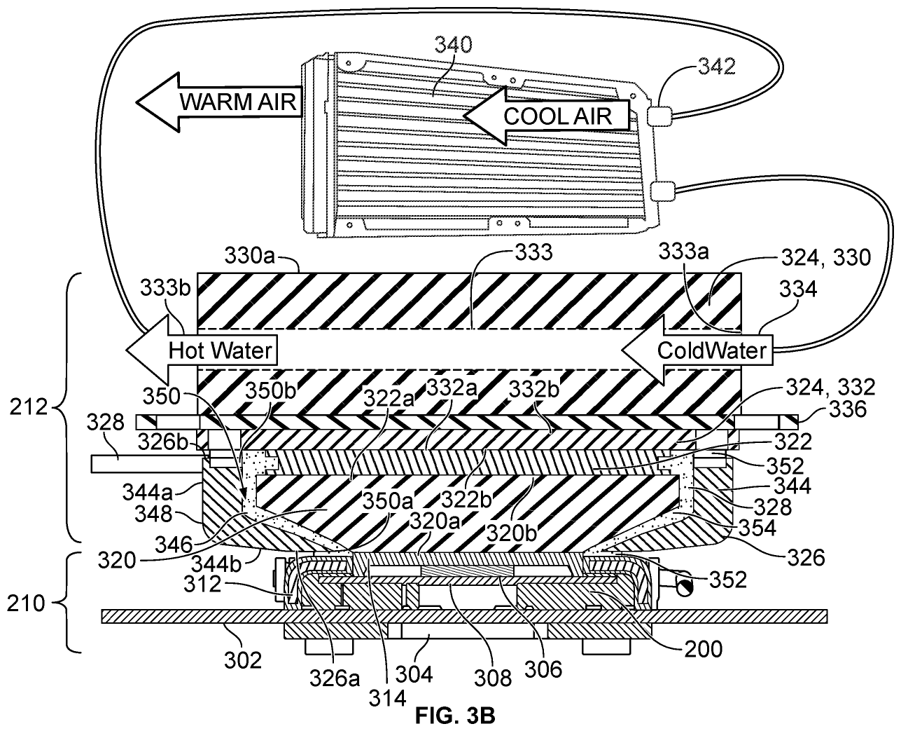

FIG. 3A is a cross-sectional, perspective view of the example sub-ambient cooler assembly 200 of FIG. 2 taken along line 3-3 of FIG. 2. FIG. 3B is a front, cross-sectional view of FIG. 3A.

Referring to FIGS. 3A and 3B, the circuit board assembly 204 of the illustrated example includes a printed circuit board (PCB) 302 (e.g., a motherboard, etc.) to support the electronic components 202. To support the PCB 302 and/or the electronic components 202, the circuit board assembly 204 includes a backing plate 304 coupled to (e.g., a first side of) the PCB 302. The electronic components 202 of the illustrated example includes a processor 306 (e.g., a system on chip (SOC), a processor die, etc.). The processor 306 can include any type of processing or electronic circuitry, such as a central processing unit (CPU), graphics processing unit (GPU), microprocessor, microcontroller, accelerator, field-programmable gate array (FPGA), etc.

The processor 306 of the illustrated example is supported by a substrate 308. To couple the substrate 308 and, thus, the processor 306 to the PCB 302 (e.g., a second side of the PCB 302 opposite the first side), the circuit board assembly 204 of the illustrated example includes a socket interface 310. In other words, the socket interface 310 of the illustrated example receives the substrate 308, to which the processor 306 is attached, to couple the processor 306 to the PCB 302. The substrate 308 and/or the socket interface 310 can include component(s) or mechanism(s) designed to couple (e.g., mechanically and/or electrically) the processor 306 (e.g., a processor die) and the PCB 302. In some examples, the processor 306, the substrate 308 and the IHS 314 form a package that can be provided as a pre-assembled and/or pre-fabricated unit. This package can be sold, manufactured and/or otherwise provided separately from the sub-ambient cooler assembly 200. For example, the package can be manufactured (and/or sold) separately from the sub-ambient cooler assembly 200.

To attach the processor 306 (e.g., the substrate 308) with the socket interface 310, the circuit board assembly 204 of the illustrated example includes an integrated loading mechanism (ILM) 312 (e.g., a mounting bracket). Specifically, the ILM 312 of the illustrated example captures, couples or otherwise retains the substrate 308 and the socket interface 310 coupled to (e.g., the second side of) the PCB 302. For example, the ILM 312 couples to the backing plate 304 via a fastener 304a that imparts a load (e.g., a compression force) to capture the substrate 308 and the socket interface 310 between the ILM 312 and the PCB 302. Although not shown in FIGS. 3A and 3B, a plurality of fasteners 304a can be used to couple the ILM 312 and the backing plate 304.

To protect to the processor 306 from damage and/or to provide a pathway for generated heat by the processor 306 to be exchanged between the processor 306 and the thermal cooling system 102 (e.g., the sub-ambient cooler assembly 200), the circuit board assembly 204 of the illustrated example includes an integrated heat spreader (IHS) 314. The IHS 314 of the illustrated example is a protective cover that is positioned on and/or couples (e.g., directly) to the processor 306 (e.g., a metal exterior lid) and/or provides an interface between the processor 306 and the sub-ambient cooler assembly 200. The IHS 314 can be integrated with the processor 306, attached (e.g., directly) to processor 306, and/or otherwise designed to spread heat generated by the processor 306. The IHS 314 can be a heat block of made from copper, aluminum and/or any type of thermally conductive material(s).

The sub-ambient cooler assembly 200 of the illustrated example includes a heat spreader 320, a thermal electric cooler (TEC) 322, a liquid cooler 324 (e.g., a first heat exchanger), and a shroud 326. To thermally couple the processor 306 and the TEC 322 (e.g., to transfer heat from the processor 306 to the TEC 322), the sub-ambient cooler assembly 200 of the illustrated example includes the heat spreader 320. The heat spreader 320 reduces thermal resistance (and/or spreading heat) and increases transfer of thermal energy by spreading heat more evenly from the processor 306 to the TEC 322. The heat spreader 320 of the illustrated example is positioned between the processor 306 and the TEC 322. For example, the heat spreader 320 of the illustrated example has a first surface 320a thermally coupled to or in thermal communication with the IHS 314 of the processor 306 and a second surface 320b opposite the first surface 320a that is thermally coupled to or in thermal communication with the TEC 322. For example, to thermally couple the heat spreader 320 with the IHS 314 and the TEC 322, the first surface 320a of the heat spreader 320 of the illustrated example can be positioned in direct engagement with the IHS 314 of the processor 306 and the second surface 320b of the heat spreader 320 can be positioned in direct engagement with the TEC 322. In some examples, a thermal interface material (TIM) can be interposed or positioned between the first surface 320a and the IHS 314 and/or between the second surface 320b and the TEC 322. Due to a size difference (e.g., a surface area) between the processor 306 and the TEC 322, the heat spreader 320 of the illustrated example has a trapezoidal-shaped, cross-section. For example, the first surface 320a of the heat spreader 320 that is oriented toward the processor 306 has a smaller dimensional profile (e.g., has a smaller surface area or perimeter) than the second surface 320b of the heat spreader 320 that is oriented toward the TEC 322. The heat spreader 320 of the illustrated example can be a block of thermally conductive material including, for example, copper (Cu), aluminum (Al), and/or any other thermally conductive metal(s), material(s) and/or alloy(s). Further, in some examples, the heat spreader 320 can be implemented as a thermal interposer (e.g., copper interposer). In some examples, the heat spreader 320 can be a heat sink or any other structure for transferring heat and/or spreading heat from the processor 306. In some examples, the heat spreader 320 provides means for spreading heat and/or means for transferring heat generated by the electronic components 202.

To remove heat from the heat spreader 320, the sub-ambient cooler assembly 200 of the illustrated example includes the TEC 322. The TEC 322 of the illustrated example is an electric device which serves as a solid-state heat pump that moves heat from a first surface 322a (e.g., a first side) of the TEC 322 to a second surface 322b (e.g., a second side) of the TEC 322 opposite the first surface 322a. The TEC 322, which is commonly referred to as a Peltier device, can include any cooling device or mechanism that relies on, or operates using, thermoelectricity and/or the Peltier effect. For example, TEC 322 can be a device having electronic junctions positioned between two surfaces or metallic plates that are designed to transfer or pump thermal energy from one surface (e.g., the first surface 322a) to the other surface (e.g., the second surface 322b) when current or voltage is applied to the TEC 322. In this manner, one surface is cooled (e.g., the first surface 322a in the orientation of FIGS. 3A and 3B) and another surface is heated (e.g., the second surface 322b in the orientation of FIGS. 3A and 3B). To provide electrical power to the TEC 322, the TEC 322 includes a power cord 328 (e.g., wires) that receives power from a power source (e.g., a battery, a power supply, etc.) of the electronic device 100. By running current or voltage to the TEC 322, the first surface 322a (e.g., a first side) of the TEC 322 is cooled to a sub-ambient temperature, which dissipates heat from the processor 306 via the heat spreader 320 to the second surface 322b of the TEC 322. In some examples, the TEC 322 can be a refrigeration system or any other device for reducing temperatures to sub-ambient temperatures. In some examples, the TEC 322 provides means for cooling the electronic components 202 to a sub-ambient temperature.

To remove or dissipate heat from the second surface 322b of the TEC 322, the sub-ambient cooler assembly 200 of the illustrated example includes the liquid cooler 324 (e.g., a heat exchanger). The TEC 322 of the illustrated example is positioned between the heat spreader 320 and the liquid cooler 324. The liquid cooler 324 of the illustrated example is a liquid-cooled system (e.g., a water-cooled system). Specifically, the liquid cooler 324 of the illustrated example includes a liquid block 330 and a cold plate 332. The cold plate 332 is proximate the TEC 322 to dissipate heat from the TEC 322 and the liquid block 330 removes the heat from the cold plate 332. The liquid block 330 and/or the cold plate 332 are formed of thermally conductive material(s) or alloy(s) (e.g., copper, aluminum, etc.).

The cold plate 332 of the illustrated example is a block of thermally conductive material (e.g., a rectangular-shaped plate). The liquid block 330 of the illustrated example is a heat exchanger that receives a heat transfer medium 334 to remove heat from the second surface 322b of the TEC 322. For example, the liquid block 330 of the illustrated example includes a flow path 333 (e.g., a plurality of passageways) formed within the liquid block 330 between an inlet 333a and an outlet 333b to receive the heat transfer medium 334 (e.g., coolant, a cooling liquid, water) to remove or dissipate heat from the second surface 322b of the TEC 322 via the cold plate 332. For example, the first surface 322a of the TEC 322 of the illustrated example is oriented toward the heat spreader 320 to remove heat from the heat spreader 320 and the second surface 322b of the TEC 322 opposite the first surface 320a is oriented toward the cold plate 332 to remove heat from the second surface 322b of the TEC 322. Thus, the first surface 322a of the TEC 322 of the illustrated example is a cooled surface (e.g., cooled to sub-ambient temperatures) that cools and/or dissipates heat generated by the processor 306 via the heat spreader 320, while the second surface 322b of the TEC 322 of the illustrated example is a heated surface that is cooled by the liquid cooler 324. The heat transfer medium 334 of the illustrated example is a water. However, in other examples, the liquid cooler 324 can include any type of liquid-based cooling system. In some examples, the liquid block 330 and/or the cold plate 332 of the illustrated example can include internal fins that increase a surface area to enhance heat transfer. In some examples, the liquid block 330 and the cold plate 332 can be combined as a unitary structure. For example, the liquid cooler 324 can be a tubed cold plate, a buried tube cold plate where metal tubes are covered with a conductive epoxy layer, a close-spaced pin fin cold plate, and/or any other cold plate, heat exchanger, heat sink, and/or thermally conductive device for removing heat from the TEC 322. In some examples, the liquid cooler 324 can be a heat exchanger, a heat sink, a heat pipe, and/or any other heat exchanger for removing heat. In some examples, the liquid cooler 324 (e.g., the liquid block 330 and/or the cold plate 332) provides means for removing heat from the TEC 322.

In the illustrated example, the sub-ambient cooler assembly 200 includes a mounting bracket 336 to couple the sub-ambient cooler assembly 200 and the PCB 302. For example, the mounting bracket 336 includes the openings 208 that align with respective ones of the openings 208 of the PCB to receive the fasteners 206 (FIG. 2). The mounting bracket 336 of the illustrated example is positioned between the cold plate 332 and the liquid block 330, and the cold plate 332 is positioned between the TEC 322 and the mounting bracket 336. In other words, in the illustrated example, a first surface 332a of the cold plate 332 engages (e.g., directly engages) the second side of the TEC 322 and a second side 332b of the cold plate 332 opposite the first surface 332a (e.g., directly) engages the mounting bracket 336. The mounting bracket 336 of the illustrated example is made from a thermally conductive material(s) (e.g., copper, aluminum, etc.) to enable the liquid block 330 to remove heat from the cold plate 332. In other examples, the mounting bracket 336 can be positioned at other locations of the sub-ambient cooler assembly 200. For example, the mounting bracket 336 can be positioned an outer surface 330a of the liquid block 330 and/or can be integrally formed with the liquid block 330. In some such examples, the cold plate 332 directly engages the liquid block 330. In some examples, the mounting bracket 336 provides a means for mounting the sub-ambient cooler 200 to the PCB 302.

To cool the heat transfer medium 334 after removing heat from the cold plate 332 and/or the second surface 322b of the TEC 322, the thermal cooling system 102 of the illustrated example employs a remote heat exchanger 340 (e.g., a second heat exchanger). For example, the remote heat exchanger 340 is a radiator that removes heat from the heat transfer medium 334 via a cooling fluid 342 (e.g., fan air). For example, the cooling fluid 342 of the illustrated example is provided by fan air that is drawn through the remote heat exchanger 340 to cool or remove heat from the heat transfer medium 334 prior to circulating the heat transfer medium 334 to the liquid block 330. In some examples, the remote heat exchanger 340 provides means for cooling or removing waste heat from the heat transfer medium 334.

The shroud 326 of the illustrated example is positioned between the cold plate 332 and the ILM 312. The shroud 326 of the illustrated example has a body or wall 344 (e.g., a rectangular-shaped body) defining an inner surface 346 (e.g., an interior surface of the wall 344) and an outer surface 348 (e.g., an exterior surface of the wall 344). The shroud 326 defines a cavity 350 to receive the heat spreader 320 and the TEC 322. Thus, the shroud 326 contains the heat spreader 320 and the TEC 322. For example, the shroud 326 (e.g., the wall 344) at least partially surrounds or encases the heat spreader 320 and the TEC 322. Specifically, a first end 326a of the shroud 326 is oriented toward (e.g., directly engages) the ILM 312 and the a second end 326b of the shroud 326 opposite the first end 326a is oriented toward (e.g., directly engages) the first surface 332a of the cold plate 332. The first end 326a of the shroud 326 of the illustrated example defines a first opening 350a having a first perimeter and the second end 326b of the shroud defines a second opening 350b having a second perimeter that is greater than the first perimeter of the first opening 350a. The wall 344 of the illustrated example has a straight wall portion 344a (e.g., a vertical wall in the orientation of FIG. 3B) and a transition 344b (e.g., angled wall portion) that tapers from the straight wall portion 344a toward a center of the shroud 326. Thus, the wall 344 of the shroud 326 of the illustrated example tapers proximate the first end 326a to reduce the first opening 350a to correspond to a perimeter of the processor 306 and the second end 326b is sized to enlarge the second opening 350b to receive the TEC 322.

To maintain, contain and/or otherwise guide the heat generated by the processor to the TEC, the sub-ambient cooler assembly 200 of the illustrated example includes a thermal insulation 354. The thermal insulation 354 is positioned in the cavity 350 of the shroud 326 between the inner surface 346 of the shroud 326 and (e.g., respective external surfaces or perimeter edges of) the TEC 322 and the heat spreader 320. Thus, the thermal insulation 354 of the illustrated example prevents or restricts heat generated by the processor 306 from leaking or dissipating sideways away from the TEC 322. The thermal insulation 354 can be formed of any suitable insulating material, foam, etc., that has any suitable thermal resistance (e.g., R-value) characteristic or rating. Additionally, the thermal insulation 354 prevents or restricts heat from the shroud 326 and/or the ILM 312 from transferring to the heat spreader 320. Further, in some examples, the thermal insulation 354 prevents or restricts air flow to the heat spreader 320 and/or the first surface 322a of the TEC 322, thereby preventing or reducing condensation from forming on the heat spreader 320 and/or the first surface 322a of the heat spreader 320. Thus, the shroud 326 contains the heat spreader 320, the TEC 322 and the thermal insulation 354. For example, the shroud 326 (e.g., the wall 344) at least partially surrounds or encases the heat spreader 320, the TEC 322, and the thermal insulation 354. In some examples, the thermal insulation 354 provides means for insulating the shroud 326 from the TEC 322 (e.g., the first side 322a of the TEC 322) and the heat spreader 320.

In the illustrated example, the first end 326a of the shroud is thermally coupled to (e.g., directly engaged with) the TEC 322 via the cold plate 332. Specifically, the cold plate 332 of the illustrated example is in engagement with (e.g., direct contact with) at least a portion of the second surface 322b of the TEC 322 and the second end 326b of the shroud 326. In other words, the cold plate 332 provides a heat transfer pathway to enable heat from the TEC 322 to transfer to the shroud 326, while the thermal insulation 354 prevents or restricts heat transfer between the shroud 326 and first surface 322a of the TEC 322 and the heat spreader 320. In some examples, the heat transfer pathway and/or the direct engagement between the shroud 326 and the cold plate 332 and/or the liquid cooler 324 provides means for removing and/or means for transferring waste heat from cold plate 332 and/or the second side 322b of the TEC 322 and the shroud 326. In some examples, the heat transfer pathway and/or the direct engagement between the shroud 326 and the cold plate 332 and/or the liquid cooler 324 provides redirecting waste heat form the liquid cooler 324 to the shroud 326.

To improve thermal conductivity, the sub-ambient assembly of the illustrated example includes thermal interface material (TIM) 352. For example, the TIM 352 of the illustrated example is positioned between the shroud 326 and the cold plate 332 to improve thermal conductivity between the cold plate 332 and the shroud 326. Additionally, the TIM 352 of the illustrated example is positioned between the shroud 326 and the ILM 312 to improve thermal conductivity between the shroud 326 and the ILM 312. The TIM 352 of the illustrated example is a thermally conductive material(s) including, for example, thermal paste, thermal adhesive, thermal gap filler, thermally conductive pad, thermal tap, and/or other thermally conductive material(s).

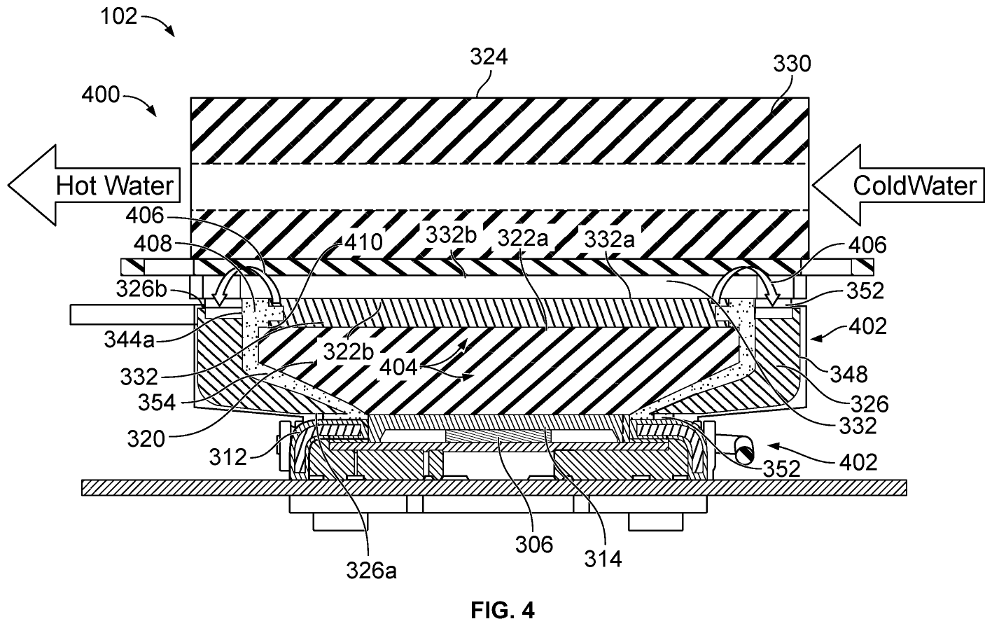

FIG. 4 is a cross-sectional view similar to FIG. 3B with a schematic heat distribution profile 400 of sub-ambient cooler assembly 200 during an example operation. In operation, power is provided to the TEC 322 via the power cord 328 to cool the first surface 322a of the TEC 322 to a temperature that is below ambient (e.g., a sub-ambient temperature of between approximately −20 degrees Celsius and 32 degrees Celsius), which also cools the heat spreader 320 (e.g., to sub-ambient temperatures). Heat generated by the processor 306 transfers to the heat spreader 320 via the IHS 314 (e.g., via conduction). The heat spreader 320 spreads the heat across the first surface 322a of the TEC 322. The heat is pumped by the TEC 322 from the first surface 322a to the second surface 322b of the TEC 322, which transfers to the cold plate 332 via engagement between the first surface 332a of the cold plate 332 and the second surface 322b of the TEC 322. For example, the first surface 322a of the TEC 322 can be cooled to approximately between −20 degrees Celsius and 32 degrees Celsius, and the second surface 322b of the TEC 322 can be heated to approximately between 15 degrees Celsius and 60 degrees Celsius. The liquid block 330 removes or dissipates the heat from the cold plate 332 via the heat transfer medium 334 that is circulated via the remote heat exchanger 340.

As noted above, the sub-ambient cooler assembly 200 of the illustrated example can be susceptible condensation. To mitigate condensation forming on external surfaces 402 of the sub-ambient cooler assembly 200 and/or the circuit board assembly 204 that can otherwise be cooled to temperatures below a dew point temperature of ambient air via the TEC 322 (e.g., when the TEC 322 cools the processor 306 to sub-ambient temperatures), the sub-ambient cooler assembly 200 of the illustrated example routes thermal energy to the external surfaces 402 via conduction. Specifically, waste heat 406 from the second surface 322b of the TEC 322 is redirected via conductive heating to the external surfaces 402 to increase surface temperatures of the external surfaces 402 to temperatures that are greater than a dewpoint temperature of ambient air. In this manner, condensation is prevented from forming on the external surfaces 402.

For example, in the illustrated example, to control or mitigate (e.g., reduce or prevent) condensation from forming on one or more surfaces of the heat spreader 320, the TEC 322 (e.g., the first surface 322a of the TEC 322), the ILM 312, the circuit board assembly 204 (e.g., via the ILM 312) and/or any other surface of the sub-ambient cooler assembly 200, the first assembly 210 and/or the circuit board assembly 204 that can be cooled by the TEC 322 to surface temperatures below a dewpoint temperature of ambient air, the shroud 326 of the illustrated example is heated during operation via the waste heat 406 from the TEC 322 (e.g., while the TEC 322 cools the processor 306 to sub-ambient temperatures). As described above, the shroud 326 of the illustrated example is thermally coupled to the cold plate 332 and/or the second surface 322b of the TEC 322. Specifically, the waste heat from the second surface 322b of the TEC 322 is redirected to the shroud 326 to raise a surface temperature of the shroud 326 (e.g., the outer surface 348) to a temperature that is greater than a dewpoint temperature of ambient air that can contact the outer surface 348 of the shroud 326. Additionally, the shroud 326 transfers heat to the ILM 312 because the first end 326a of the shroud 326 is in engagement with (e.g., directly engages) the ILM 312. Thus, the waste heat 406 from the second surface 322b of the TEC 322 increases a temperature of the ILM 312 via conductive heating provided by a thermal connection between the shroud 326 and the ILM 312. Thus, the TEC 322 increases a surface temperature of the ILM 312 via the shroud 326 to a temperature that is greater than a dewpoint temperature of ambient air. Increasing the surface temperatures of the shroud 326 and/or the ILM 312 significantly reduces, mitigates and/or prevents condensation from forming on the shroud 326, the ILM 312 (e.g., when the first surface 322a of the TEC 322 cools the heat spreader 320 to sub-ambient temperatures), and/or the circuit board assembly 204. The TIM 352 increases and/or facilitates heat transfer between the shroud 326 and the cold plate 332 and between the shroud 326 and the ILM 312. Thus, the transfer of thermal energy from the second surface 322b of the TEC 322, to the cold plate 332, to the shroud 326 and to the ILM 312 is achieved via a heat transfer pathway provided via contact (e.g., direct engagement and/or engagement via the TIM 352) between the shroud 326 and the first surface 332a of the cold plate 332 which is in contact (e.g., direct contact and/or via the TIM 352) with the second surface 322b of the TEC 322. For example, the cold plate 332 overlaps or extends beyond side surfaces (e.g., a perimeter) of the TEC 322 to engage with the second end 326b of the shroud 326. Thus, the cold 332 of the illustrated example provides a heat transfer pathway to transfer waste heat 406 from the TEC 322 to the shroud 326.

The external surfaces 402 (e.g., the outer surface 348 of the shroud 326 and an external surface 412 of the ILM 312) are isolated from cooler internal surfaces 404 (e.g., the heat spreader 320 and the TEC 322) that are cooled by the first surface 322a of the TEC 322 via the thermal insulation 354. For example, a portion 408 of the thermal insulation 354 projects past the second end 326b of the shroud 326 and engages the first surface 332a of the cold plate 332 between the TEC 322 (e.g., a lateral side or perimeter edge 410 of the TEC 322) and the inner surface 346 of the wall 344 of the shroud 326. Thus, the shroud 326 is thermally coupled to the second surface 322b of the TEC 322 via engagement with the first surface 332a of the cold plate 332. Likewise, the cooler internal surfaces 404 are isolated or insulated from warmer external surfaces 402 via the thermal insulation 354. Because the temperature of the external surfaces 402 is greater than a dewpoint temperature of ambient air, condensation is mitigated or prevented from forming in the external surfaces 402. Additionally, increasing the temperatures of the external surfaces 402 do not affect an efficiency of the TEC 322 and/or an amount at which the processor 306 can be cooled because the external surfaces 402 are insulated from the internal surfaces 404 via the thermal insulation 354. Thus, by redirecting waste heat 406 to the shroud 326 and/or the ILM 312, the sub-ambient cooler assembly 200 mitigates and/or prevents condensation from forming and/or falling proximate the PCB 302, the electronic components 202 and/or the processor 306 by increasing surface temperatures of surfaces that come into contact with ambient air. By increasing the surface temperatures of the external surfaces, the external surfaces 402 become less susceptible to condensation because the external surfaces 402 cannot cool the air temperature proximate the external surfaces 402 to a temperature that is less than the dewpoint temperature of the ambient air proximate and/or in contact with the external surfaces 402.

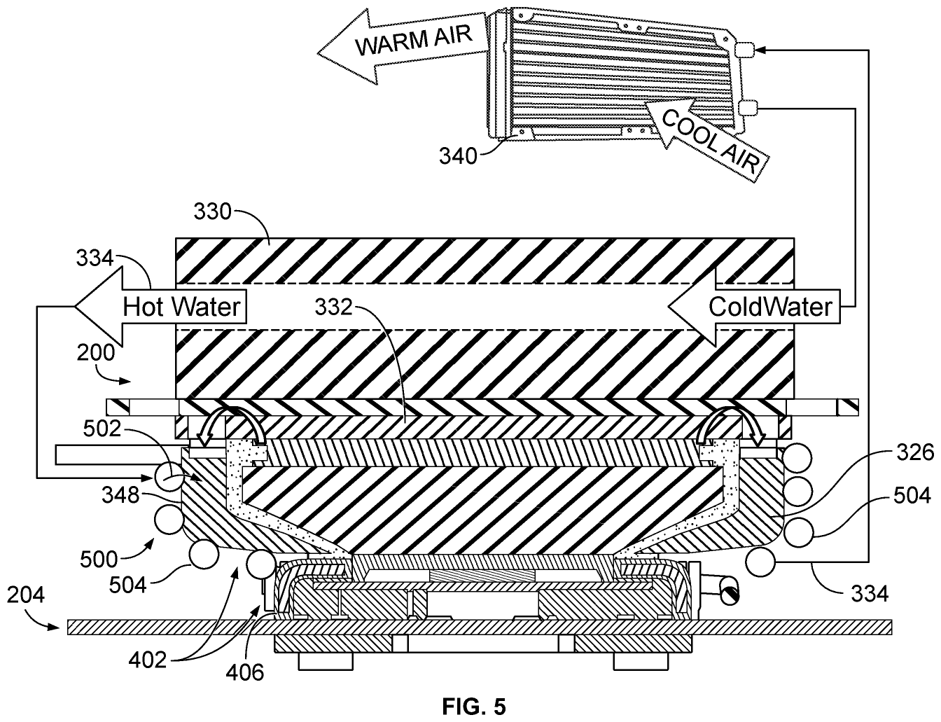

FIG. 5. is a cross-sectional view of the sub-ambient cooler assembly 200 implemented with an example supplemental heating system 500 disclosed herein. The supplemental heating system 500 of the illustrated example employs waste heat 502 from the liquid cooler 430 to increase a temperature of the external surfaces 402 of the sub-ambient cooler assembly 200 and/or the circuit board assembly 204. For example, prior to recirculating the heat transfer medium 334 exiting the liquid block 330 to the remote heat exchanger 340, the supplemental heating system 500 of the illustrated example directs the heat transfer medium 334 to one or more external surfaces 402. Specifically, the supplemental heating system 500 of the illustrated example includes tubing 504 (e.g., pipes) coupled to (e.g., directly engages) the outer surface 348 of the shroud 326. For example, the tubing 504 is wrapped around (e.g., in a spiral pattern around) the external surface 334b of the wall 344 of the shroud 326. The tubing 504 can be formed of thermally conductive material(s) or alloy(s) (e.g., copper, aluminum, etc.). The tubing 504 can be coupled to the outer surface 348 via a fastener (e.g., a weld, a bracket, etc.) and/or can be retained against the outer surface 348 of the wall 344 via friction, a compressive spring force, a clamp, a weld, and/or another fastener. In some examples, at least a portion of the tubing 504 can be integrally formed with the shroud 326.

In operation, the heat transfer medium 334 removes or dissipates heat from the cold plate 332, thereby increasing a temperature of the heat transfer medium 334. As the heated heat transfer medium 334 exits the liquid block 330, the heat transfer medium 334 passes through the tubing 504 that is wrapped around (e.g., coiled around) the outer surface 348 of the shroud 326. Heat from the heat transfer medium 334 transfers to the outer surface 348 of the shroud 326 via conduction due to the engagement between the tubing 504 and the shroud 326. As a result, the heat transfer medium 334 causes a temperature of the outer surface 348 of the shroud 326 to increase to mitigate, reduce and/or prevent condensation from forming on the shroud 326. Additionally, the heat from the heat transfer medium 334 transfers to the ILM 312 via the thermal connection between the shroud 326 and the ILM 312. Additionally or alternatively, the tubing 504 can be positioned or coupled to the ILM 312 to increase a temperature of the external surface 412 of the ILM 312.

After the heat transfer medium 334 flows through the tubing 504 to increase the temperature of the shroud 326, the heat transfer medium 334 returns to the remote heat exchanger 340. The supplemental heat system 500 further increases an efficiency of the remote heat exchanger 340 because a temperature of the heat transfer medium 334 returning to the remote heat exchanger 340 for cooling is less than the temperature of the heat transfer medium 334 exiting the liquid block 330 that would otherwise circulate to the remote heat exchanger 340 as shown in FIGS. 3A, 3B and 4. In some examples, the supplemental heat system 500 (e.g., the tubing 504) provides means for removing and/or means for transferring waste heat from cold plate 332 and/or the second side 322b of the TEC 322 to the shroud 326. In some examples, the supplemental heat system 500 (e.g., the tubing 504) provides redirecting waste heat form the liquid cooler 324 to the shroud 326.

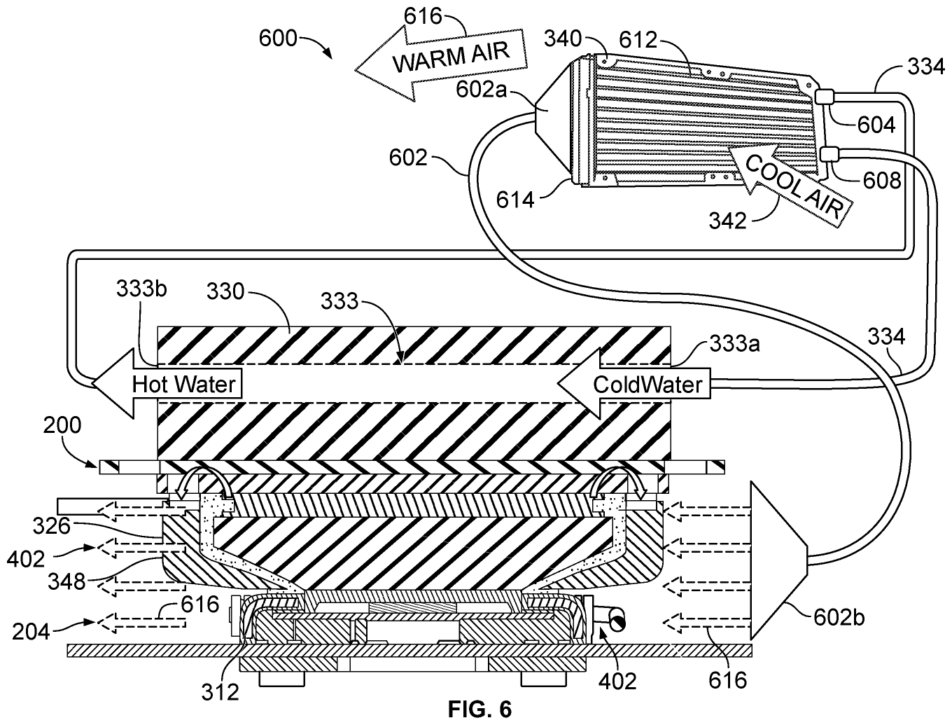

FIG. 6. is a cross-sectional view of the sub-ambient cooler assembly 200 implemented with another example supplemental heating system 600 disclosed herein. The supplemental heating system 600 of the illustrated example increases surface temperatures of the external surfaces 402 of the sub-ambient cooler assembly 200 and/or the circuit board assembly 204 via convection heating. For example, the supplemental heating system 600 of the illustrated example includes a duct 602 (e.g., an air duct) that fluidly couples the remote heat exchanger 340 and the sub-ambient cooler assembly 200 and/or the circuit board assembly 204. For example, the remote heat exchanger 340 includes a heat medium inlet 604 to receive the heat transfer medium 334 from the outlet 333b of the liquid block 330 and a heat medium outlet 608 to provide the heat transfer medium 334 to the inlet 333a of the liquid block 330. The remote heat exchanger 340 removes heat from the heat transfer medium 334 to reduce a temperature of the heat transfer medium 334 as the heat transfer medium 334 flows between the heat medium inlet 604 and the heat medium outlet 608. The cooling fluid 342 (e.g., fan air) passes through a secondary inlet 612 of the remote heat exchanger 340 flows through the remote heat exchanger 340 to a secondary outlet 614 as heated exhaust 616. For example, the cooling fluid 342 is fan air that is drawn through the secondary inlet 612. As the cooling fluid 342 flows from the secondary inlet 612 to the secondary outlet 614, the cooling fluid 342 removes heat from the heat transfer medium 334 flowing through the remote heat exchanger 340 between the heat medium inlet 604 and the heat medium outlet 608, thereby increasing a temperature of the cooling fluid 342 exiting the secondary outlet 614 and decreasing a temperature of the heat transfer medium 334 entering the inlet 333a of the liquid block 330. The cooling fluid 342 exits the secondary outlet 614 as heated exhaust 616.

In operation, waste heat from the heated exhaust 616 from the cooling fluid 342 exiting the secondary outlet 614 is directed to the sub-ambient cooler assembly 200 via the duct 602. For example, the duct 602 includes a duct inlet 602a in fluid communication with the secondary outlet 614 and a duct outlet 602b in fluid communication with the external surfaces 402 of the sub-ambient cooler assembly 200 and/or the circuit board assembly 204. Thus, the duct 602 channels the waste heat from the heated exhaust 616 exiting the secondary outlet 614 toward the external surfaces 402 of the sub-ambient cooler assembly 200 and/or the circuit board assembly 204 (e.g., via convection). For example, the cooling fluid 342 flows across the outer surface 348 of the shroud 326 and/or the outer surface of the ILM 312 to increase surface temperatures of the shroud 326 and the ILM 312 (e.g., via convention) to temperatures that are greater than a dewpoint temperature of the air. In some examples, the supplemental heat system 600 (e.g., the duct 602) provides means for removing and/or means for transferring waste heat from cold plate 332 and/or the second side 322b of the TEC 322 to the shroud 326. In some examples, the supplemental heat system 600 (e.g., the duct 602) provides redirecting waste heat form the liquid cooler 324 to the shroud 326.

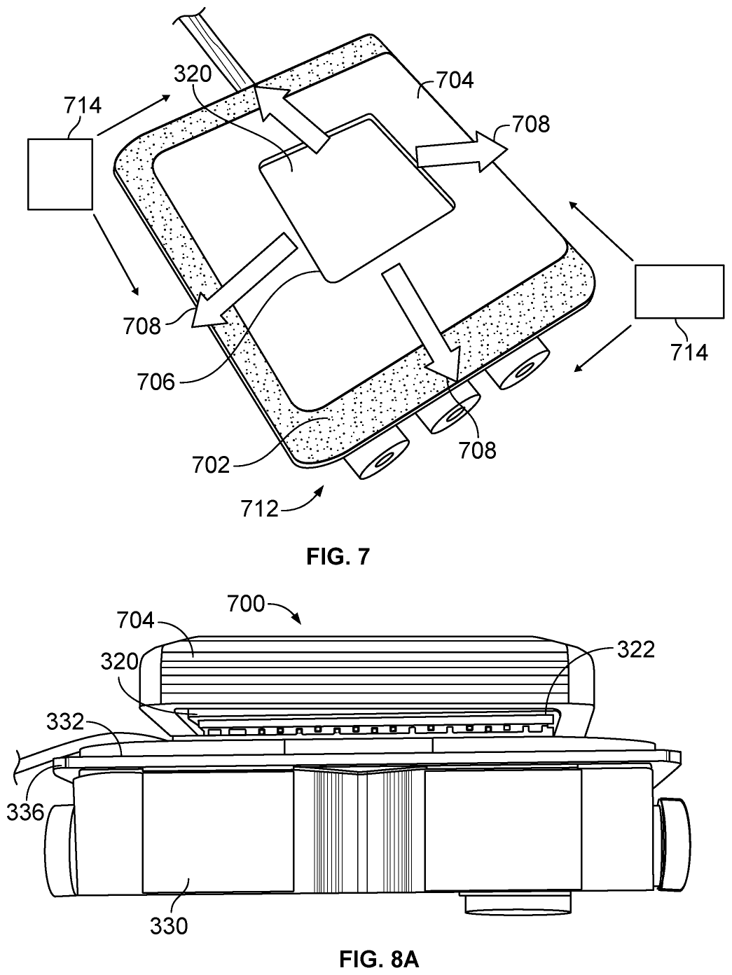

FIG. 7 is another example sub-ambient cooler assembly 700 disclosed herein. The sub-ambient cooler assembly 700 can be removably coupled to the circuit board assembly 204 of FIG. 2 in place of the sub-ambient cooler assembly 200 of FIG. 2. Many of the components of the example sub-ambient cooler assembly 700 of FIG. 7 are substantially similar or identical to the components described above in connection with FIGS. 1, 2, 3A, 3B, and 4-6. As such, those components will not be described in detail again below. Instead, the interested reader is referred to the above corresponding descriptions for a complete written description of the structure and operation of such components. To facilitate this process, similar or identical reference numbers will be used for like structures in FIG. 7 as used in FIGS. 1, 2, 3A, 3B, and 4-6.

Referring to FIG. 7, the sub-ambient cooler assembly 700 of the illustrated example includes wick or wicking material 702 to provide a flow path for moisture to exit the sub-ambient cooler assembly 700 without affecting the processor 306, electronic components 202, and/or other electronic components 202 of the circuit board assembly 204 (FIG. 2). The wicking material 702 of the illustrated example is positioned between a shroud 704 and a liquid cooler 324. Specifically, the wicking material 702 of FIG. 7 is captured (e.g., sandwiched) between the shroud 704 and the liquid cooler 324. The shroud 704 of the illustrated example has a first opening 706 (e.g., a rectangular shaped opening) to expose a heat spreader 320 for thermal communication with a processor 306 (e.g., the IHS 314 and/or the processor 306 of FIGS. 2, 3A, 3B, and 4-5).

The wicking material 702 of the illustrated example is a pad or wicking medium that provides a flow path 708 that moves moisture from cooler regions or locations (e.g., adjacent the heat spreader 320) to warmer regions or locations (e.g., remote from the heat spreader) for evaporation. The wicking material 702 of the illustrated example has a square or rectangular profile. Additionally, one or more fans 714 can be employed to provide warmer airflow across the remote locations 712 to facilitate evaporation of moisture from the wicking material 702. In some examples, warmer airflow across at least portions of the wicking material 702 and/or the remote location 712 can be provided by captured waste heat (e.g., the heated exhaust 616 from the cooling fluid 342 exiting the secondary outlet 614 can be directed across at least portions of the wicking material 702 and/or the remote location 712 via the duct 602). In some examples, the fans 714 can be omitted. In some examples, the wicking material 702 provides means for transferring condensation from a first location (e.g., the warmer region) to a second location (e.g., a cooler region remote from the first location. In some examples, the wicking material 702 provides means for defining a fluid flow path for condensation to flow from a first location (e.g., the warmer region) to a second location (e.g., a cooler region remote from the first location.

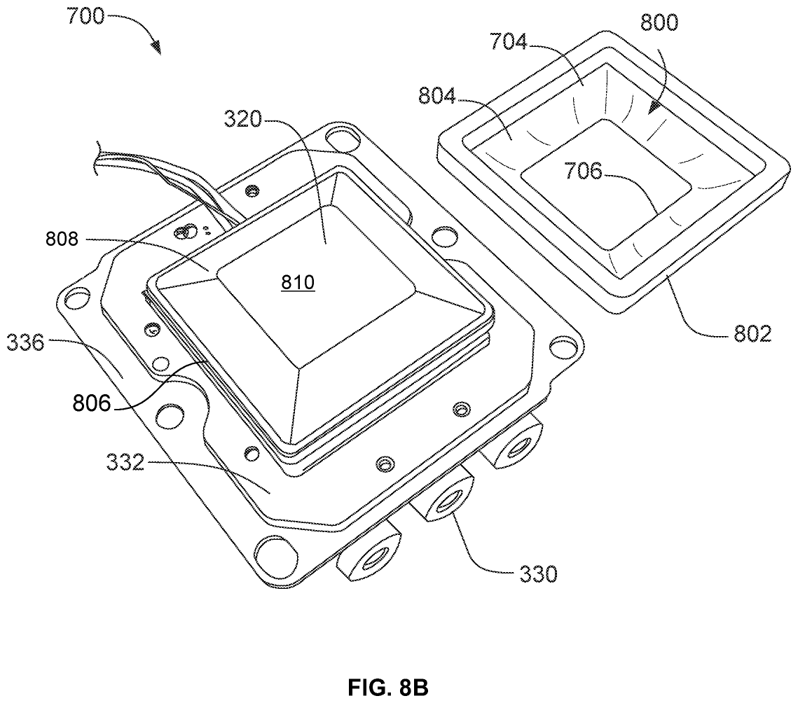

FIG. 8A is a side view of the example sub-ambient cooler assembly 700 of FIG. 7 but shown without the wicking material 702. FIG. 8B is a partially assembled view of the example sub-ambient cooler assembly 700 of FIG. 7 shown with the shroud 704 removed. The sub-ambient cooler assembly 700 includes a TEC 322 positioned between the heat spreader 320 and a cold plate 332 of the liquid cooler 324. The cold plate 332 is positioned between the TEC 322 and the mounting bracket 336. The liquid block 330 is positioned proximate the mounting bracket 336 and receives a heat medium transfer fluid (e.g., the heat transfer medium 334 of FIG. 3) to cool and/or remove heat from the TEC 322 via the cold plate 332 and the mounting bracket 336. When the wicking material 702 is positioned between the shroud 704 and the cold plate 332, the wicking material 702 at least partially surrounds or encases the heat spreader 320 and/or the TEC 322. In the illustrated example, the wicking material 702 completely surrounds a perimeter of the heat spreader 320 and/or a perimeter of the TEC 322.

The shroud 704 of the illustrated example has a cavity 800 that receives the heat spreader 320. Thus, the shroud 704 of the illustrated example has a shape and/or profile complementary to the shape and/or profile of the heat spreader 320. For example, the shroud 702 of the illustrated example includes a base 802 and an upper surface 804 defining the opening 706. The base 802 defines sidewalls having a rectangular shape and the upper surface 804 defines sidewalls having a pyramid-like shape. For example, the sidewalls defined by the upper surface 804 taper inwardly from the base 802 toward the opening 706. When covered to the heat spreader 320, the base 802 of the shroud 702 covers sidewalls 806 (e.g., forming rectangular shaped or square shaped base) of the heat spreader 320 and the upper surface 804 covers sidewalls 808 (e.g., tapering sidewalls forming a pyramid-like shape). An upper surface 810 (e.g., a flat surface) of the heat spreader 320 is exposed via the opening 706. The shroud 704 of the illustrated example is composed of a plastic material. In some examples, the shroud 704 can have a square shape, or rectangular shape, a cup shape, and/or any other shape and/or can be composed of any other material(s) and/or alloy(s).

In operation, the wicking material 702 provides a wicking medium to absorb and transport condensation that can form on external surfaces of the sub-ambient cooler assembly 700 and/or the circuit board assembly 204 of FIGS. 2, 3A, 3B, and 4-6. For example, the wicking material 702 receives (e.g., catches) condensation that can form on external surfaces 402 (e.g., exterior surfaces) of the sub-ambient cooler assembly 700 and/or the circuit board assembly 204 that can be cooled by the TEC 322 to surface temperatures that are less than a dewpoint temperature of ambient air. For example, condensation can form on exterior surfaces of the heat spreader 320, a first surface 322a of the TEC 322, and/or any other surfaces of the sub-ambient cooler assembly 700. Additionally, condensation can form on exterior surfaces of the ILM 312 and/or other components of the circuit board assembly 204 of FIGS. 2, 3A, 3B, and 4-5.

The wicking material 702 absorbs the condensation that can form on the external surfaces 402 and transports the moisture and/or condensation via capillary action to an area remote or away from the processor 306 (FIGS. 3A and 3B), the PCB 302 and/or any other electronic components 202 of the circuit board assembly 204 (FIG. 2). For instance, the wicking material 702 provides the flow path 708 (e.g., in the direction of the arrows of FIG. 7) to transfer moisture from an area (e.g., a first location 710) susceptible to condensation to an area (e.g., a second location 712) exposed to or having a higher temperature (e.g., with a lower moisture content). Higher temperatures at the end of the flow path provided by the wicking material 702 evaporate the moisture.

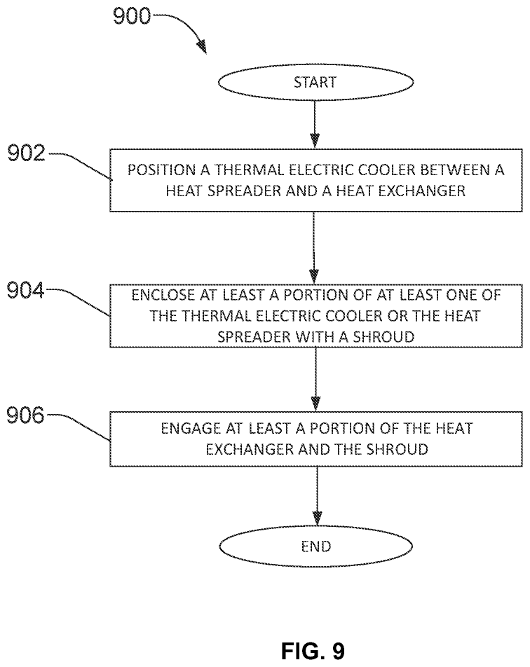

FIG. 9 is a flowchart of an example method 900 of manufacturing an example sub-ambient cooler assembly disclosed herein. For example, the method 900 can be used to assemble the sub-ambient cooler assembly 200 of FIGS. 2, 3A, 3B and 4-6. To facilitate the discussion, the example method 900 is described in connection with the example sub-ambient cooler assembly 200 of FIGS. 2, 3A, 3B and 4-6. While an example manner of forming the example sub-ambient cooler assembly 200 has been illustrated in FIG. 9, one of the steps and/or processes illustrated in FIG. 9 can be combined, divided, re-arranged, omitted, eliminated and/or implemented in any other way. Further still, the example method 900 of FIG. 9 can include processes and/or steps in addition to, or instead of, those illustrated in FIG. 9 and/or may include more than one of any or all of the illustrated processes and/or steps. Further, although the example methods are described with reference to the flowchart illustrated in FIG. 9, many other methods or processes of forming electronic packages may alternatively be used.

Referring to the example method 900 of FIG. 9, the method 900 begins by positioning the TEC 322 between the heat spreader 320 and the shroud 326. The shroud 326 is to enclose at least a portion of the at least one of the TEC 322 and the heat spreader 320 (block 904). Additionally, the shroud 326 is to be formed from metal (e.g., copper, aluminum, etc.) or alloy material(s) having thermal conductive characteristics (e.g., thermal conductivity between approximately 200 and 400 Watts per meter-Kelvin (W/(m·K)) to spread heat across a significant surface area (e.g., between 50 percent and 100 percent of the surface area) of the shroud 326. The shroud 326 is positioned to engage (e.g., directly engage) at least a portion of the liquid cooler 324 (e.g., the cold plate 332) to enable heat (e.g., waste heat 406) from the liquid cooler 324 to transfer to the shroud 326 to increase a surface temperature of the shroud 326 (block 906). In some examples, a first flow path (e.g., tubing 504) is formed or provided (e.g., wrapped) proximate the shroud 326 to channel waste heat from a heat transfer medium 334 to the shroud 326. In some examples, a second flow path (e.g., the duct 602) is formed or provided to channel waste heat or exhaust air from the remote heat exchanger 340 to the shroud 326.

The foregoing examples of the thermal systems can be employed with electronic devices such as, for example, desktop computers, mobile devices, laptops, portable computers and/or any other computer(s) or electronic devices having electronic components that are susceptible to condensation. Although each example thermal systems disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. For instance, an example sub-ambient cooler assembly disclosed herein can include the supplemental heating system 500 of FIG. 5 and the supplemental heating system 600 of FIG. 6. In some examples, the sub-ambient cooler assembly 200 of FIGS. 2, 3A, 3B, and 4-6 can include a wicking material of FIG. 7.

From the foregoing, it will be appreciated that example methods, apparatus and articles of manufacture have been disclosed to mitigate, prevent and/or absorb condensation that can form during sub-ambient cooling conditions. For example, the example methods, apparatus and articles of manufacture disclosed herein mitigate and/or prevent condensation by increasing surface temperatures of components susceptible to condensation form sub-ambient coolers via conduction and/or convention by redirecting waste heat generated by heat exchangers. In some examples, the example methods, apparatus and articles of manufacture disclosed herein mitigate condensation by absorbing condensation that forms adjacent components having sub-ambient temperatures and transporting the absorbed condensation or moisture to a remote location having a higher temperature to evaporate the moisture back into the air.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc. may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, and (7) A with B and with C. As used herein in the context of describing structures, components, items, objects and/or things, the phrase “at least one of A and B” is intended to refer to implementations including any of (1) at least one A, (2) at least one B, and (3) at least one A and at least one B. Similarly, as used herein in the context of describing structures, components, items, objects and/or things, the phrase “at least one of A or B” is intended to refer to implementations including any of (1) at least one A, (2) at least one B, and (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, and (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, and (3) at least one A and at least one B.

As used herein, singular references (e.g., “a”, “an”, “first”, “second”, etc.) do not exclude a plurality. The term “a” or “an” entity, as used herein, refers to one or more of that entity. The terms “a” (or “an”), “one or more”, and “at least one” can be used interchangeably herein. Furthermore, although individually listed, a plurality of means, elements or method actions may be implemented by, e.g., a single unit or processor. Additionally, although individual features may be included in different examples or claims, these may possibly be combined, and the inclusion in different examples or claims does not imply that a combination of features is not feasible and/or advantageous.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent

Example electronic packages and related methods are disclosed. Further examples and combinations thereof include, but are not limited to, the following:

Example 1 includes an example sub-ambient cooling assembly including a heat spreader, a thermal electric cooler, and a heat exchanger, where the thermal electric cooler positioned between the heat spreader and the heat exchanger. A shroud is to at least partially surround the heat spreader and the thermal electric cooler. The heat exchanger is to transfer heat to the shroud to increase a surface temperature of the shroud.

Example 2 includes the subject matter of example 1, including thermal insulation positioned between the shroud and the heat spreader

Example 3 includes the subject matter of any one of examples 1-2, wherein the thermal insulation directly engages an internal surface of the shroud and an exterior surface of the heat spreader

Example 4 includes the subject matter of any one of examples 1-3, wherein the thermal electric cooler has a first side in thermal communication with the heat spreader and a second side opposite the first side in thermal communication with the heat exchanger.

Example 5 includes the subject matter of any one of examples 1-4, wherein at least a portion of an exterior surface of the heat exchanger is in direct contact with at least a portion of the shroud to enable heat to transfer from the heat exchanger to the shroud.

Example 6 includes the subject matter of any one of examples 1-5, including a radiator to remove heat from the heat exchanger after the heat exchanger removes heat from the thermal electric cooler.

Example 7 includes the subject matter of any one of examples 1-6, including a blower to direct exhaust air from the radiator across at least a portion of an external surface of the shroud.

Example 8 includes the subject matter of any one of examples 1-7, including a pipe coupled to an exterior surface of the shroud, the pipe fluidly coupled to an outlet of the heat exchanger, wherein the pipe is to receive heat transfer medium that exits from the heat exchanger to increase a surface temperature of the shroud.

Example 9 includes the subject matter of any one of examples 1-8, including a mounting plate to couple the sub-ambient cooling assembly to a circuit board supporting the electronic component.

Example 10 includes the subject matter of any one of examples 1-9, wherein the mounting plate is coupled to the heat exchanger.

Example 11 includes a sub-ambient cooler assembly including a heat spreader, a heat exchanger, a thermal electric cooler positioned between the heat exchanger and the heat spreader, and a wicking material positioned proximate the thermal electric cooler. The wicking material to receive condensed water proximate at least one of the thermal electric cooler or the heat spreader. The wicking material is to channel the condensed water to a location remote from the at least one of the thermal electric cooler or the heat spreader.

Example 12 includes the subject matter of example 11, further including a shroud.

Example 13 includes the subject matter of any one of examples 11-12, wherein the wicking material is positioned between the shroud and the heat exchanger.

Example 14 includes the subject matter of any one of examples 11-13, wherein the wicking material is to at least partially surround at least one of the thermal electric cooler or the heat spreader.

Example 15 includes the subject matter of any one of examples 11-14, further including a fan located adjacent the remote location to evaporate the condensed water from the wicking material.

Example 16 includes the subject matter of any one of examples 11-15, wherein the wicking material encases the heat spreader and the thermal electric cooler.

Example 17 includes the subject matter of any one of examples 11-16, wherein the wicking material is a pad having a thickness, the wicking material having a first side proximate a first side of the heat spreader and a second side opposite the first side that is proximate a second side of the thermal electric cooler.

Example 18 recites a method including positioning a thermal electric cooler between a heat spreader and a heat exchanger, enclosing at least a portion of at least one of the thermal electric cooler or a heat spreader with a shroud, and engaging at least a portion of the heat exchanger and the shroud to enable heat to transfer from the heat exchanger to the shroud to increase a surface temperature of the shroud.

Example 19 includes the subject matter of example 18, further including channeling a heat transfer medium from the heat exchanger to the shroud to transfer heat from the heat transfer medium to the shroud after the heat transfer medium removes heat from the thermal electric cooler.

Example 20 includes the subject matter of any one of examples 18-20, further including channeling exhaust air from a radiator across the shroud to increase a surface temperature of the shroud.

Example 21 includes a sub-ambient cooler assembly including means for spreading heat generated by an electronic component, means for cooling the electronic component to a sub-ambient temperature, means for removing heat from the means for cooling, the means for cooling being positioned between the means for spreading and the means for removing heat, and means for at least partially encasing the means for spreading heat and the means for cooling, the means for removing heat to transfer waste heat to the means for at least partially encasing to increase a surface temperature of the means for at least partially encasing.

Example 22 includes the subject matter of example 21, further including means for insulating positioned between the means for at least partially surrounding and the means for spreading heat.

Example 23 includes the subject matter of any one of examples 21-23, further including means for redirecting waste heat form the means for removing heat to the means for at least partially encasing

The following claims are hereby incorporated into this Detailed Description by this reference, with each claim standing on its own as a separate embodiment of the present disclosure.

What is claimed is:

1. A sub-ambient cooling assembly comprising:
a heat spreader;
a thermal electric cooler;
a heat exchanger, the thermal electric cooler positioned between the heat spreader and the heat exchanger; and
a shroud to at least partially surround the heat spreader and the thermal electric cooler, the heat exchanger to transfer heat to the shroud to increase a surface temperature of the shroud.

2. The assembly as defined in claim 1, further including thermal insulation positioned between the shroud and the heat spreader.

3. The assembly as defined in claim 2, wherein the thermal insulation directly engages an internal surface of the shroud and an exterior surface of the heat spreader.

4. The assembly as defined in claim 1, wherein the thermal electric cooler has a first side in thermal communication with the heat spreader and a second side opposite the first side in thermal communication with the heat exchanger.

5. The assembly as defined in claim 1, wherein at least a portion of an exterior surface of the heat exchanger is in direct contact with at least a portion of the shroud to enable heat to transfer from the heat exchanger to the shroud.

6. The assembly as defined in claim 1, further including a radiator to remove heat from the heat exchanger after the heat exchanger removes heat from the thermal electric cooler.

7. The assembly as defined in claim 6, further including a blower to direct exhaust air from the radiator across at least a portion of an external surface of the shroud.

8. The assembly as defined in claim 1, further including a pipe coupled to an exterior surface of the shroud, the pipe fluidly coupled to an outlet of the heat exchanger, wherein the pipe is to receive heat transfer medium that exits from the heat exchanger to increase a surface temperature of the shroud.

9. The assembly as defined in claim 1, further including a mounting plate to couple the sub-ambient cooling assembly to a circuit board supporting the electronic component.

10. The assembly as defined in claim 9, wherein the mounting plate is coupled to the heat exchanger.

11. A sub-ambient cooler assembly comprising:
a heat spreader;
a heat exchanger;
a thermal electric cooler positioned between the heat exchanger and the heat spreader; and
a wicking material positioned proximate the thermal electric cooler, the wicking material to receive condensed water proximate at least one of the thermal electric cooler or the heat spreader, the wicking material is to channel the condensed water to a location remote from the at least one of the thermal electric cooler or the heat spreader.

12. The assembly as defined in claim 11, further including a shroud.

13. The assembly as defined in claim 12, wherein the wicking material is positioned between the shroud and the heat exchanger.

14. The assembly as defined in claim 11, wherein the wicking material is to at least partially surround at least one of the thermal electric cooler or the heat spreader.

15. The assembly as defined in claim 11, further including a fan located adjacent the remote location to evaporate the condensed water from the wicking material.

16. The assembly as defined in claim 11, wherein the wicking material encases the heat spreader and the thermal electric cooler.

17. The assembly as defined in claim 11, wherein the wicking material is a pad having a thickness, the wicking material having a first side proximate a first side of the heat spreader and a second side opposite the first side that is proximate a second side of the thermal electric cooler.

18. A method comprising:
positioning a thermal electric cooler between a heat spreader and a heat exchanger;
enclosing at least a portion of at least one of the thermal electric cooler or a heat spreader with a shroud; and
engaging at least a portion of the heat exchanger and the shroud to enable heat to transfer from the heat exchanger to the shroud to increase a surface temperature of the shroud.

19. The method as defined in claim 18, further including channeling a heat transfer medium from the heat exchanger to the shroud to transfer heat from the heat transfer medium to the shroud after the heat transfer medium removes heat from the thermal electric cooler.

20. The method as defined in claim 18, further including channeling exhaust air from a radiator across the shroud to increase a surface temperature of the shroud.
